(19) United States
(12) Patent Application Publication
(10) Pub. No.: US 2014/0291146 A1
(43) Pub. Date: Oct. 2, 2014

(54) SPUTTERING APPARATUS

(71) Applicant: Samsung Display Co., Ltd., Yongin-City (KR)

(72) Inventors: Jae-Yun Sim, Yongin-City (KR); Seung-Ho Choi, Yongin-City (KR)

(73) Assignee: Samsung Display Co., Ltd., Yongin-City (KR)

(21) Appl. No.: 13/945,779

(22) Filed: Jul. 18, 2013

(30) Foreign Application Priority Data
Mar. 28, 2013 (KR) 10-2013-0033662

(51) Int. Cl. C23C 14/35

(52) U.S. Cl. CPC C23C 14/35
USPC 204/298.12

(57) ABSTRACT

A sputtering apparatus capable of effectively reducing damage of a target in a sputtering process includes a first magnet assembly extending in a first direction and having a first side surface and a second side surface extending in the first direction, which correspond to each other, and has a first bottom surface extending in the first direction, which connects the first and second side surfaces; a first shield on the first side surface of the first magnet assembly; and a first supporter for supporting a first end and a second end of a first cylindrical tubular target, the first cylindrical tubular target having a first longitudinal axis parallel to the first direction, the first cylindrical tubular target accommodating the first magnet assembly and the first shield.

### CROSS-REFERENCE TO RELATED APPLICATION

This application claims priority to and the benefit of Korean Patent Application No. 10-2013-0033662, filed on Mar. 28, 2013, in the Korean Intellectual Property Office, the disclosure of which is incorporated herein in its entirety by reference.

### BACKGROUND

1. Field

The present invention relates to a sputtering apparatus, and more particularly, to a sputtering apparatus capable of effectively reducing damage of a target in a sputtering process.

2. Description of the Related Art

In general, a sputtering apparatus is used to deposit a thin film and is an apparatus for accelerating a gas, e.g., argon, ionized in plasma, allowing the gas to collide with a target, and thus, ejecting desired atoms to form a film on a substrate located near the apparatus. For example, a magnetron sputtering apparatus may increase a deposition rate by allowing electrons to stay near a target by using a magnetic field and inducing continuous ionization to cause concentrated sputtering.

However, by using the above-described sputtering apparatus, plasma may also be formed in an undesired region. The plasma formed in an undesired region is referred to as parasitic plasma and causes arcing at an end portion of a target toward a supporting portion.

### SUMMARY

The present invention provides a sputtering apparatus capable of effectively reducing damage of a target in a sputtering process. However, the present invention is not limited thereto.

According to an aspect of the present invention, there is provided a sputtering apparatus including: a first magnet assembly extending in a first direction, including a first side surface and a second side surface each extending in the first direction, which correspond to each other, and including a first bottom surface extending in the first direction, which connects the first side surface and the second side surface; a first shield on the first side surface of the first magnet assembly; and a first supporter for supporting a first end and a second end of a first cylindrical tubular target, the first cylindrical tubular target having a first longitudinal axis parallel to the first direction, the first cylindrical tubular target accommodating the first magnet assembly and the first shield.

The first supporter may include a first motor configured to rotate the first cylindrical tubular target about the first longitudinal axis.

The first shield may extend in the first direction along the first side surface of the first magnet assembly.

The first shield may protrude from the first bottom surface of the first magnet assembly.

The first shield may be on at least a portion of the first bottom surface of the first magnet assembly.

The sputtering apparatus further include a first additional shield on the second side surface of the first magnet assembly.

The first shield may be configured to reduce an intensity of a magnetic field in an outer region of the first shield with respect to the first magnet assembly.

The sputtering apparatus may further include: a second magnet assembly extending in the first direction, including a third side surface and a fourth side surface each extending in the first direction, which correspond to each other, and including a second bottom surface extending in the first direction, which connects the third and fourth side surfaces, wherein the third side surface is adjacent to the second side surface of the first magnet assembly; a second shield on the fourth side surface of the second magnet assembly; and a second supporter for supporting a first end and a second end of a second cylindrical tubular target, the second cylindrical tubular target having a second longitudinal axis parallel to the first direction. Here, the second cylindrical tubular target may accommodate the second magnet assembly and the second shield.

The second supporter may include a second motor configured to rotate the second cylindrical tubular target about the second longitudinal axis.

The second shield may protrude from the second bottom surface of the second magnet assembly.

The second shield may be on at least a portion of the second bottom surface of the second magnet assembly.

The sputtering apparatus may further include a second additional shield on the third side surface of the second magnet assembly.

The second shield may be configured to reduce an intensity of a magnetic field in an outer region of the second shield with respect to the second magnet assembly.

According to an aspect of the present invention, there is provided a sputtering apparatus including: a first magnet assembly extending in a first direction, including a first side surface and a second side surface each extending in the first direction, which correspond to each other, and including a first bottom surface extending in the first direction, which connects the first side surface and the second side surface; a first shield on the first side surface of the first magnet assembly and protruding from the first bottom surface of the first magnet assembly; a first additional shield on the second side surface of the first magnet assembly and protruding from the first bottom surface of the first magnet assembly; a second magnet assembly extending in the first direction, including a third side surface and a fourth side surface extending in the first direction, which correspond to each other, and comprising a second bottom surface extending in the first direction, which connects the third side surface and the fourth side surface, the third side surface being adjacent to the second side surface of the first magnet assembly; a second shield on the fourth side surface of the second magnet assembly and protruding from the second bottom surface of the second magnet assembly; a second additional shield on the third side surface of the second magnet assembly and protruding from the second bottom surface of the second magnet assembly; a first supporter for supporting a first end and a second end of a first cylindrical tubular target, the first cylindrical tubular target having a first longitudinal axis parallel to the first direction, the first cylindrical tubular target accommodating the first magnet assembly and the first shield; and a second supporter for supporting a first end and a second end of a second cylindrical tubular target, the second cylindrical tubular target having a second longitudinal axis parallel to the first direction, the second cylindrical tubular target accommodating the second magnet assembly and the second shield.

The first shield may be configured to reduce an intensity of a magnetic field in an outer region of the first shield with respect to the first magnet assembly, and the second shield may be configured to reduce an intensity of a magnetic field in an outer region of the second shield with respect to the second magnet assembly.

According to an aspect of the present invention, there is provided a sputtering apparatus including: a first magnet assembly extending in a first direction, including a first side surface and a second side surface each extending in the first direction, which correspond to each other, and including a first bottom surface extending in the first direction, which connects the first side surface and the second side surface; a first shield on the first side surface of the first magnet assembly and on at least a portion of the first bottom surface of the first magnet assembly; a first additional shield on the second side surface of the first magnet assembly and on at least a portion of the first bottom surface of the first magnet assembly; a second magnet assembly extending in the first direction, including a third side surface and a fourth side surface extending in the first direction, which correspond to each other, and including a second bottom surface extending in the first direction, which connects the third side surface and the fourth side surface, the third side surface being adjacent to the second side surface of the first magnet assembly; a second shield on the fourth side surface of the second magnet assembly and on at least a portion of the second bottom surface of the second magnet assembly; a second additional shield on the third side surface of the second magnet assembly and on at least a portion of the second bottom surface of the second magnet assembly; a first supporter for supporting a first end and a second end of a first cylindrical tubular target, the first cylindrical tubular target having a first longitudinal axis parallel to the first direction, the first cylindrical tubular target accommodating the first magnet assembly and the first shield; and a second supporter for supporting a first end and a second end of a second cylindrical tubular target, the second cylindrical tubular target having a second longitudinal axis parallel to the first direction, wherein the second cylindrical tubular target accommodating the second magnet assembly and the second shield.

The first shield may be configured to reduce an intensity of a magnetic field in an outer region of the first shield with respect to the first magnet assembly, and the second shield may be configured to reduce an intensity of a magnetic field in an outer region of the second shield with respect to the second magnet assembly.

### BRIEF DESCRIPTION OF THE DRAWINGS

The above and other features and aspects of the present invention will become more apparent by describing in detail exemplary embodiments thereof with reference to the attached drawings, in which:

FIG. 1 is a partial perspective view of a sputtering apparatus according to an embodiment of the present invention;

FIG. 2 is a conceptual view showing that a thin film is formed on a substrate by using the sputtering apparatus illustrated in FIG. 1;

FIG. 3 is a partial plan view of the sputtering apparatus illustrated in FIG. 1;

FIG. 4 is a conceptual view showing that parasitic plasma is generated by using a sputtering apparatus according to a comparative example;

FIG. 5 is a conceptual view showing magnetic field lines of the sputtering apparatus illustrated in FIG. 4;

FIG. 6 is an image showing that parasitic plasma is generated by the sputtering apparatus illustrated in FIG. 4;

FIG. 7 is an image showing that parasitic plasma is not generated by the sputtering apparatus illustrated in FIG. 1;

FIG. 8 is a conceptual view showing that a thin film is formed on a substrate by using a sputtering apparatus according to another embodiment of the present invention; and

FIG. 9 is a conceptual view showing that a thin film is formed on a substrate by using a sputtering apparatus according to another embodiment of the present invention.

### DETAILED DESCRIPTION

Aspects and features of present invention will now be described more fully with reference to the accompanying drawings, in which exemplary embodiments of the invention are shown. The present invention may be embodied in many different forms and should not be construed as being limited to the embodiments set forth herein; rather, these embodiments are provided so that this disclosure will be thorough and complete, and will fully convey the present invention to one of ordinary skill in the art.

The sizes of elements may be exaggerated in the drawings for convenience of explanation. For example, sizes and thicknesses of elements in the drawings may be arbitrarily provided for convenience of explanation, and thus, do not restrict the scope of the present invention.

In the following description, x, y, and z axes are not limited to three axes on an orthogonal coordinate system, and may be interpreted in a broader sense. For example, the x, y, and z axes may be orthogonal or non-orthogonal to each other.

It will be understood that when an element, such as a layer, a region, or a substrate, is referred to as being “on” another element, it may be “directly on” the other element or one or more intervening elements may also be present.

As used herein, the term “and/or” includes any and all combinations of one or more of the associated listed items.

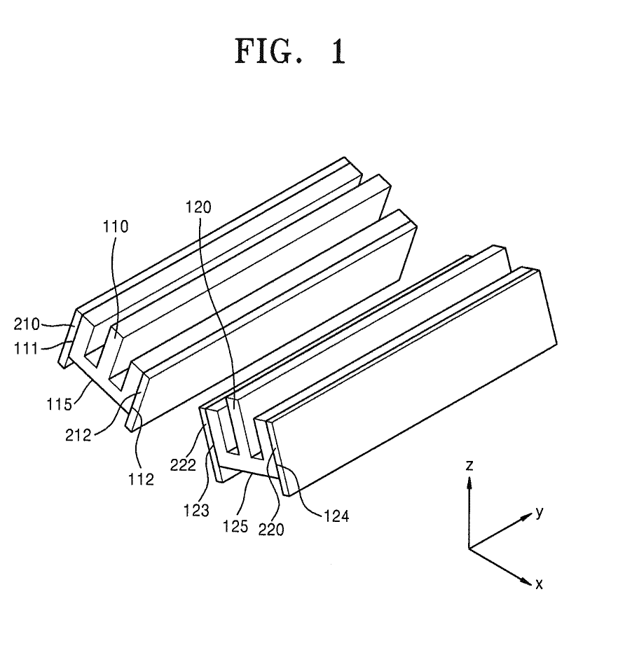

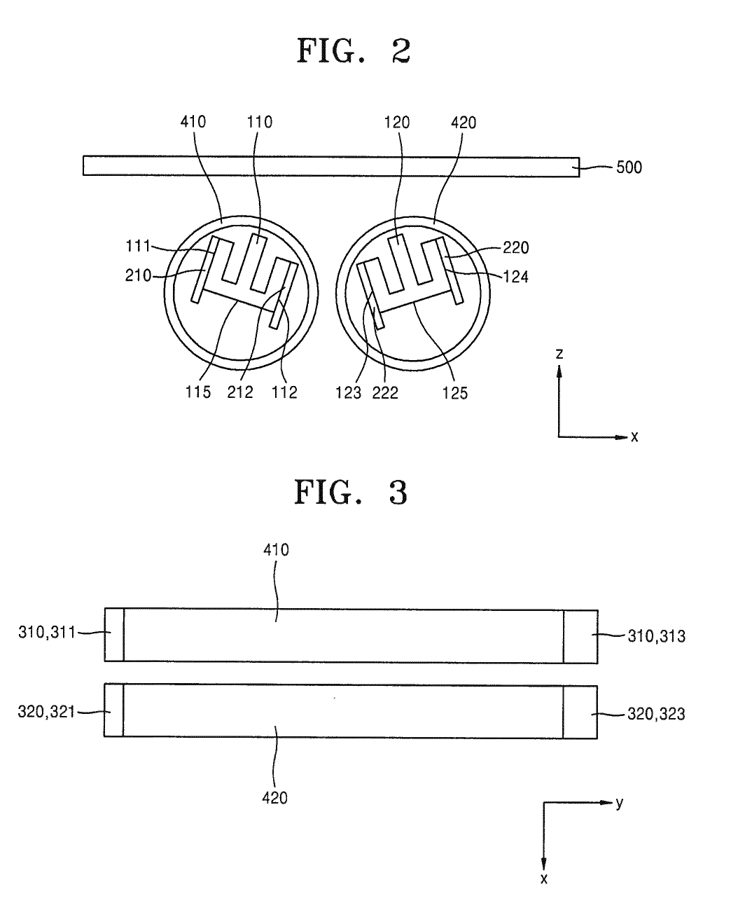

FIG. 1 is a partial perspective view of a sputtering apparatus according to an embodiment of the present invention. FIG. 2 is a conceptual view showing that a thin film is formed on a substrate 500 by using the sputtering apparatus illustrated in FIG. 1. FIG. 3 is a partial plan view of the sputtering apparatus illustrated in FIG. 1.

The sputtering apparatus according to the current embodiment includes a first magnet assembly 110, a first shield 210, a first additional shield 212, a second magnet assembly 120, a second shield 220, a second additional shield 222, a first supporter 310, and a second supporter 320.

In the current embodiment, the first magnet assembly 110 extends in a first direction (e.g., +y direction). Here, the first magnet assembly 110 has a first side surface 111 and a second side surface 112 extending in the first direction (e.g., +y direction), which correspond to each other, and a first bottom surface 115 extending in the first direction (e.g., +y direction) and connecting the first and second side surfaces 111 and 112. The first magnet assembly 110 may include a plurality of magnets extending in parallel to the first direction (e.g., +y direction).

A first cylindrical tubular target 410 may be mounted around the first magnet assembly 110. The first cylindrical tubular target 410 may be mounted to locate the first magnet assembly 110 therein. As will be described below, in addition to the first magnet assembly 110, the first shield 210 or the first additional shield 212 may also be located in the first cylindrical tubular target 410.

The first cylindrical tubular target 410 has a first longitudinal axis that may be located in parallel to the first direction (e.g., +y direction). The first magnet assembly 110 may form a magnetic field around an outer surface of the first cylindrical tubular target 410 mounted therewith, and thus, may allow plasma to be located around the outer surface of the first cylindrical tubular target 410, thereby increasing the efficiency of sputtering. In this case, a target material of the first cylindrical tubular target 410 is separated from the first cylindrical tubular target 410 and moves onto the substrate 500, such that a thin film formed of the target material is formed on the substrate 500.

In the current embodiment, the second magnet assembly 120 extends in the first direction (e.g., +y direction) like the first magnet assembly 110, and has a third side surface 123 and a fourth side surface 124 extending in the first direction (e.g., +y direction), which correspond to each other, and a second bottom surface 125 extending in the first direction (e.g., +y direction) and connecting the third and fourth side surfaces 123 and 124. The second magnet assembly 120 may include a plurality of magnets extending in parallel to first direction (e.g., +y direction).

A second cylindrical tubular target 420 is mounted around the second magnet assembly 120. The second cylindrical tubular target 420 may be mounted to locate the second magnet assembly 120 therein. As will be described below, in addition to the second magnet assembly 120, the second shield 220 and/or the second additional shield 222 may also be located in the second cylindrical tubular target 420.

The second cylindrical tubular target 420 has a second longitudinal axis that may be located in parallel to the first direction (e.g., +y direction). The second magnet assembly 120 may form a magnetic field around an outer surface of the second cylindrical tubular target 420 mounted therewith, and thus, may allow plasma to be located around the outer surface of the second cylindrical tubular target 420, thereby increasing the efficiency of sputtering. In this case, a target material of the second cylindrical tubular target 420 is separated from the second cylindrical tubular target 420 and moves onto the substrate 500, such that a thin film formed of the target material is formed on the substrate 500.

The second magnet assembly 120 may be disposed adjacent to the first magnet assembly 110. As illustrated in FIGS. 1 and 2, the third side surface 123 of the second magnet assembly 120 may be disposed adjacent to the second side surface 112 of the first magnet assembly 110. In this case, when the first and second cylindrical tubular targets 410 and 420 are mounted in the sputtering apparatus, the first and second cylindrical tubular targets 410 and 420 may be disposed to be adjacent to each other and to be spaced apart from each other by a preset distance.

If the first cylindrical tubular target 410 is mounted to locate the first magnet assembly 110 therein, ends (e.g., one end and the other end, or a first end and a second end) of the first cylindrical tubular target 410 may be supported by the first supporter 310. The first supporter 310 may have a first one end supporter 311 for supporting the one end (e.g. in the −y direction) of the first cylindrical tubular target 410, and a first the other end supporter 313 for supporting the other end (e.g., in the +y direction) of the first cylindrical tubular target 410, wherein the first the other end supporter 313 may include a first motor for rotating the mounted first cylindrical tubular target 410 about the first longitudinal axis.

Similarly, if the second cylindrical tubular target 420 is mounted to locate the second magnet assembly 120 therein, ends (e.g., one end and the other end) of the second cylindrical tubular target 420 may be supported by the second supporter 320. The second supporter 320 has a second one end supporter 321 for supporting the one end (e.g., in the −y direction) of the second cylindrical tubular target 420, and a second the other end supporter 323 for supporting the other end (e.g., in the +y direction) of the second cylindrical tubular target 420, wherein the second the other end supporter 323 may include a second motor for rotating the mounted second cylindrical tubular target 420 about the second longitudinal axis.

If the first and second cylindrical tubular targets 410 and 420 are mounted on the sputtering apparatus, the first magnet assembly 110 in the first cylindrical tubular target 410 and the second magnet assembly 120 in the second cylindrical tubular target 420 may not be respectively located at the center of the first cylindrical tubular target 410 and the center of the second cylindrical tubular target 420. For example, as illustrated in FIG. 2, the first and second magnet assemblies 110 and 120 may lean toward the substrate 500 (e.g., in the +z direction) on which a thin film of the first and second cylindrical tubular targets 410 and 420 is to be formed. As such, a target material may be separated from the first and second cylindrical tubular targets 410 and 420 toward the substrate 500 on which a thin film is to be formed and may move onto the substrate 500. Because the first and second cylindrical tubular targets 410 and 420 may rotate in a sputtering process after being mounted on the sputtering apparatus, a target material may be uniformly separated from surfaces of the first and second cylindrical tubular targets 410 and 420.

As mentioned above, the first and second cylindrical tubular targets 410 and 420 may rotate in a sputtering process after being mounted on the sputtering apparatus. In this case, the first magnet assembly 110 in the first cylindrical tubular target 410 and the second magnet assembly 120 in the second cylindrical tubular target 420 may not rotate.

The first shield 210 is located on the first side surface 111 of the first magnet assembly 110. Because the first side surface 111 of the first magnet assembly 110 extends in the first direction (e.g., +y direction), the first shield 210 may have a shape extending in the first direction (e.g., +y direction). Also, the first shield 210 may have a shape protruding from the first bottom surface 115 of the first magnet assembly 110. The first additional shield 212 may have a shape similar to that of the first shield 210, and may be located on the second side surface 112 of the first magnet assembly 110 adjacent to the second magnet assembly 120.

In the current embodiment, the second shield 220 is located on the fourth side surface 124 of the second magnet assembly 120. Because the fourth side surface 124 of the second magnet assembly 120 extends in the first direction (e.g., +y direction), the second shield 220 may have a shape extending in first direction (e.g., +y direction). Also, the second shield 220 may have a shape protruding from the second bottom surface 125 of the second magnet assembly 120. The second additional shield 222 may have a shape similar to that of the second shield 220, and may be located on the third side surface 123 of the second magnet assembly 120 adjacent to the first magnet assembly 110.

In the above-described sputtering apparatus according to the current embodiment, due to the first shield 210, the first additional shield 212, the second shield 220, and the second additional shield 222, the amount of parasitic plasma may be reduced.

As described above in relation to the related art, a sputtering apparatus is an apparatus for accelerating a gas, e.g., argon, ionized in plasma, allowing the gas to collide with a target, and thus ejecting desired atoms to form a film on the substrate 500 located near the apparatus. In particular, a magnetron sputtering apparatus may increase a deposition rate by allowing electrons to stay near a target by using a magnetic field and inducing continuous ionization to cause concentrated sputtering.

In the above-described sputtering apparatus, if plasma exists in a region other than a preset (or predefined) region, that is, if parasitic plasma exists, arcing, for example, may be caused at an end portion of a target toward a supporting portion. However, in the sputtering apparatus according to the current embodiment, due to the first shield 210, the first additional shield 212, the second shield 220, and the second additional shield 222, parasitic plasma may not be generated or may be greatly reduced in its amount, and thus, arcing may not be generated.

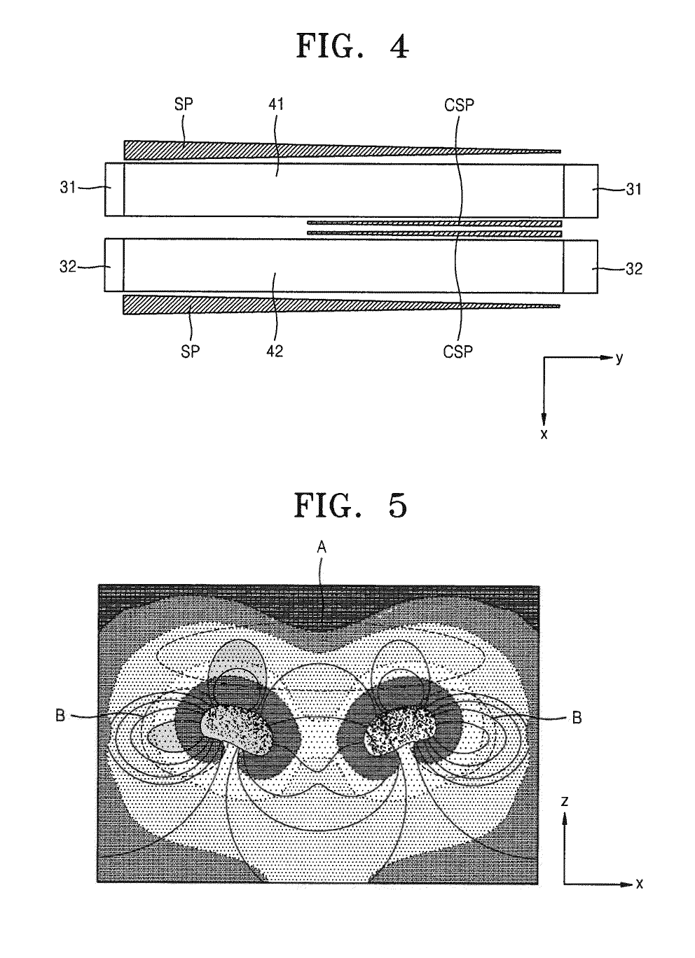

FIG. 4 is a conceptual view showing parasitic plasma generated by using a sputtering apparatus according to a comparative example. Referring to FIG. 4, parasitic plasma SP exists at an outer side of a first cylindrical tubular target 41 in a direction (e.g., −x direction) opposite to another direction (e.g., +x direction) toward a second cylindrical tubular target 42, and an outer side of the second cylindrical tubular target 42 in a direction (e.g., +x direction) opposite to another direction (e.g., −x direction) toward the first cylindrical tubular target 41. In addition, central parasitic plasma CSP may exist between the first and second cylindrical tubular targets 41 and 42.

FIG. 5 is a conceptual view showing magnetic field lines of the sputtering apparatus illustrated in FIG. 4. Referring to FIG. 5, a magnetic field exits to locate main plasma required for sputtering in a region A in a substrate direction (e.g., +z direction) from the first and second cylindrical tubular targets 41 and 42. However, in addition to the region A, a magnetic field also exists in a region B at an outer side of the first cylindrical tubular target 41 in a direction (e.g., −x direction) opposite to another direction (e.g., +x direction) toward the second cylindrical tubular target 42, and an outer side of the second cylindrical tubular target 42 in a direction (e.g., +x direction) opposite to another direction (e.g., −x direction) toward the first cylindrical tubular target 41. Plasma that exists in the region B is the parasitic plasma SP illustrated in FIG. 4.

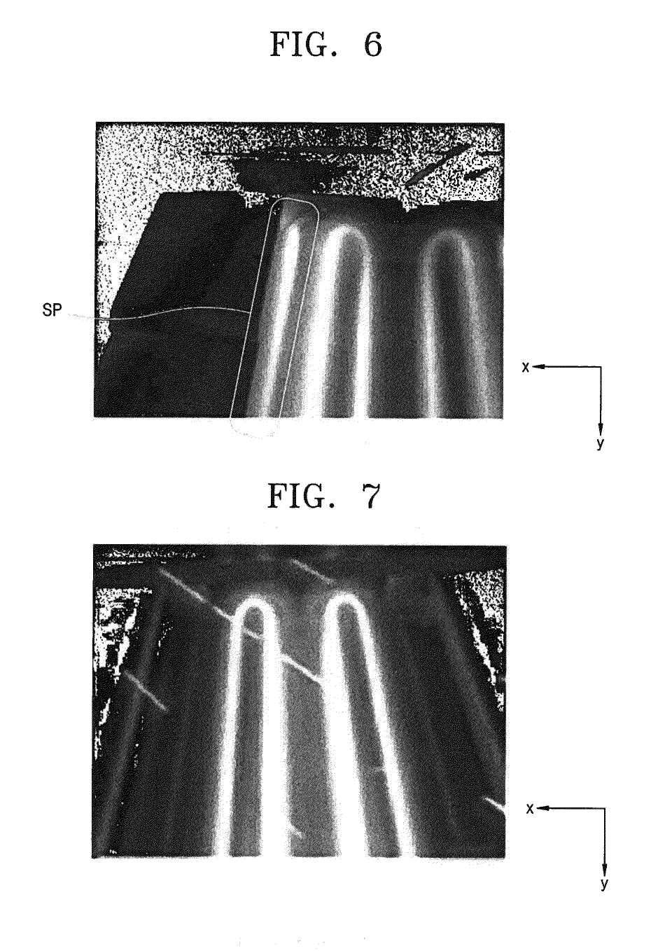

FIG. 6 is an image showing that the parasitic plasma SP is generated by the sputtering apparatus illustrated in FIG. 4. In FIG. 6, plasma other than the parasitic plasma SP is located in a substrate direction (e.g., +z direction) from the first and second cylindrical tubular targets 41 and 42.

The plasma other than the parasitic plasma SP allows a target material in the first and second cylindrical tubular targets 41 and 42 to be separated from the first and second cylindrical tubular targets 41 and 42 and to move onto a substrate. The parasitic plasma SP may also allow a target material in the first and second cylindrical tubular targets 41 and 42 to be separated from the first and second cylindrical tubular targets 41 and 42. However, because it is not adjacent to the substrate, the separated target material may not move onto the substrate and moves back toward the first and second cylindrical tubular targets 41 and 42 so as to be redeposited.

Arching may be generated in the above-described redeposition process. The arcing damages the first and second cylindrical tubular targets 41 and 42, and thus, reduces the efficiency of sputtering. For example, as illustrated in FIG. 4, a larger amount of the parasitic plasma SP exits near the −y direction of a first supporter 31 and the −y direction of a second supporter 32. As such, arcing is generated near −y direction ends of the first and second cylindrical tubular targets 41 and 42.

However, in the sputtering apparatus according to the current embodiment, due to the first shield 210, the first additional shield 212, the second shield 220, and the second additional shield 222, parasitic plasma may not be generated or may be greatly reduced in its amount, and thus, arcing may not be generated or may be greatly reduced in its intensity or frequency.

That is, the first shield 210 may reduce the intensity of a magnetic field in an outer region of the first shield 210 with respect to the first magnet assembly 110 (for example, the region B in the −x direction in FIG. 5). If the intensity of a magnetic field in the region B is reduced, the amount of plasma, i.e., parasitic plasma, located in the corresponding region B may be reduced. Similarly, the second shield 220 may reduce the intensity of a magnetic field in an outer region of the second shield 220 with respect to the second magnet assembly 120 (for example, the region B in the +x direction in FIG. 5). Accordingly, the amount of plasma, i.e., parasitic plasma, located in the corresponding region B may be reduced. Similarly, the first additional shield 212 or the second additional shield 222 may reduce the intensity of a magnetic field between the first and second magnet assemblies 110 and 120 such that the central parasitic plasma CSP between the first and second cylindrical tubular targets 410 and 420 may not exist or may be greatly reduced in its amount. FIG. 7 is an image showing that parasitic plasma is not generated by the sputtering apparatus illustrated in FIG. 1.

As described above, in the sputtering apparatus according to the current embodiment, because plasma may exist only in a space between the first and second cylindrical tubular targets 410 and 420 and the substrate 500, and parasitic plasma in another space may not exist or may be greatly reduced in its amount. As such, a sputtering apparatus having an excellent efficiency and capable of preventing arcing, may be achieved.

The above-described first shield 210, the first additional shield 212, the second shield 220, and the second additional shield 222 may include, for example, copper (Cu). In addition to Cu, any material capable of blocking a magnetic field may also be used. If the first shield 210, the first additional shield 212, the second shield 220, and the second additional shield 222 are formed of a material including Cu, they may have a thickness of about 3 mm to about 6 mm. According to some embodiments, when the thickness is less than about 3 mm, a magnetic field may not be appropriately shielded, and if the thickness is greater than about 6 mm, a whole structure including a magnet assembly, a shield, and an additional shield may have a large volume, and thus, may not easily be accommodated in a cylindrical tubular target.

As illustrated in FIG. 5, a magnetic field may also exist in the region B at an outer side of the first cylindrical tubular target 41 in a direction (e.g., −x direction) opposite to another direction (e.g., +x direction) toward the second cylindrical tubular target 42, and an outer side of the second cylindrical tubular target 42 in a direction (e.g., +x direction) opposite to another direction (e.g., −x direction) toward the first cylindrical tubular target 41. Plasma that exists in the region B is the parasitic plasma SP illustrated in FIG. 4.

In this case, as illustrated in FIG. 5, a magnetic field for generating the parasitic plasma SP is formed between a −x direction side surface and a bottom surface of a first magnet assembly in the first cylindrical tubular target 41, and between a +x direction side surface and a bottom surface of a second magnet assembly in the second cylindrical tubular target 42. Accordingly, because the first shield 210 for covering the first side surface 111, which may be a −x direction side surface of the first magnet assembly 110 in the first cylindrical tubular target 410, not only covers the first side surface 111 but also protrudes from the first bottom surface 115, and the second shield 220 for covering the fourth side surface 124, which may be a +x direction side surface of the second magnet assembly 120 in the second cylindrical tubular target 420, not only covers the fourth side surface 124 but also protrudes from the second bottom surface 125, the intensity of a magnetic field that causes parasitic plasma may be further reduced. This is because the first and second shields 210 and 220 respectively protruding from the first and second bottom surfaces 115 and 125 block paths of magnetic field lines to be formed if the first and second shields 210 and 220 do not exit.

The first additional shield 212 for covering the second side surface 112, which may be a +x direction side surface of the first magnet assembly 110 in the first cylindrical tubular target 410, may also protrude from the first bottom surface 115 of the first magnet assembly 110, and the second additional shield 222 for covering the third side surface 123, which may be a −x direction side surface of the second magnet assembly 120 in the second cylindrical tubular target 420, may also protrude from the second bottom surface 125 of the second magnet assembly 120. In this case, the intensity of a magnetic field that causes the central parasitic plasma CSP between the first and second cylindrical tubular targets 410 and 420 may also be further reduced.

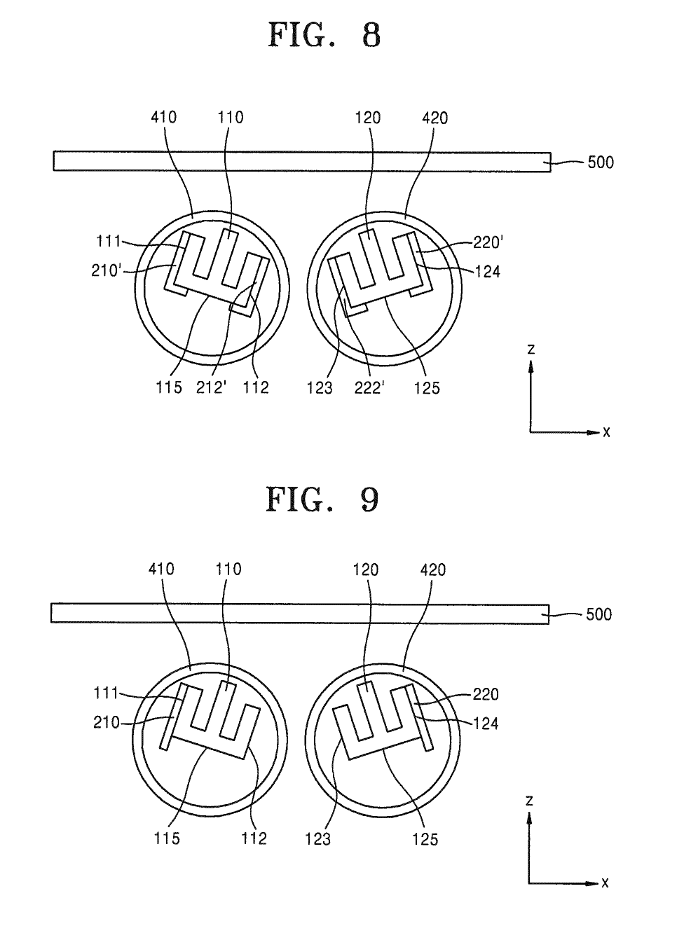

FIG. 8 is a conceptual view showing that a thin film may be formed on a substrate by using a sputtering apparatus according to another embodiment of the present invention. The sputtering apparatus according to the current embodiment is different from the sputtering apparatus according to the previous embodiment in shapes of the first shield 210, the first additional shield 212, the second shield 220, and the second additional shield 222.

In the sputtering apparatus according to the previous embodiment, the first shield 210, the first additional shield 212, the second shield 220, and the second additional shield 222 are respectively located on the first side surface 111 of the first magnet assembly 110, the second side surface 112 of the first magnet assembly 110, the fourth side surface 124 of the second magnet assembly 120, and the third side surface 123 of the second magnet assembly 120. In addition, the first shield 210 and the first additional shield 212 protrude from the first bottom surface 115 of the first magnet assembly 110, and the second shield 220 and the second additional shield 222 protrude from the second bottom surface 125 of the second magnet assembly 120.

In the sputtering apparatus according to the current embodiment, the locations of a first shield 210′, a first additional shield 212′, a second shield 220′, and a second additional shield 222′ are not changed. However, unlike the sputtering apparatus according to the previous embodiment, the first shield 210′ and the first additional shield 212′ are bent to be further located on at least portions of the first bottom surface 115 of the first magnet assembly 110, the second shield 220′ and the second additional shield 222′ are bent to be further located on at least portions of the second bottom surface 125 of the second magnet assembly 120. That is, the first shield 210′ and the first additional shield 212′ are bent to cover at least portions of the first bottom surface 115 of the first magnet assembly 110, and the second shield 220′ and the second additional shield 222′ are bent to cover at least portions of the second bottom surface 125 of the second magnet assembly 120.

As illustrated in FIG. 5, a magnetic field for generating the parasitic plasma SP is formed between a −x direction side surface and a bottom surface of a first magnet assembly in the first cylindrical tubular target 41, and between a +x direction side surface and a bottom surface of a second magnet assembly in the second cylindrical tubular target 42. Accordingly, because the first shield 210′ for covering the first side surface 111 that is a −x direction side surface of the first magnet assembly 110 in the first cylindrical tubular target 410 is bent to cover at least a portion of the first bottom surface 115 of the first magnet assembly 110, and the second shield 220′ for covering the fourth side surface 124 that is a +x direction side surface of the second magnet assembly 120 in the second cylindrical tubular target 420 is bent to cover at least a portion of the second bottom surface 125 of the second magnet assembly 120, the intensity of a magnetic field that causes parasitic plasma may be further reduced.

The first additional shield 212′ for covering the second side surface 112 that is a +x direction side surface of the first magnet assembly 110 in the first cylindrical tubular target 410 may also be bent to cover at least a portion of the first bottom surface 115 of the first magnet assembly 110, and the second additional shield 222′ for covering the third side surface 123 that is a −x direction side surface of the second magnet assembly 120 in the second cylindrical tubular target 420 may also be bent to cover at least a portion of the second bottom surface 125 of the second magnet assembly 120. In this case, the intensity of a magnetic field that causes the central parasitic plasma CSP between the first and second cylindrical tubular targets 410 and 420 may also be further reduced.

FIG. 9 is a conceptual view showing that a thin film may be formed on a substrate by using a sputtering apparatus according to another embodiment of the present invention.

As described above in relation to FIG. 4, in the sputtering apparatus according to the comparative example, the central parasitic plasma CSP exists between the first and second cylindrical tubular targets 41 and 42. However, the amount of the central parasitic plasma CSP is less than that of the parasitic plasma SP that exists at an outer side of the first cylindrical tubular target 41 in a direction (e.g., −x direction) opposite to another direction (e.g., +x direction) toward the second cylindrical tubular target 42, and an outer side of the second cylindrical tubular target 42 in a direction (e.g., +x direction) opposite to another direction (e.g., −x direction) toward the first cylindrical tubular target 41.

Accordingly, in the sputtering apparatus according to the current embodiment, unlike the sputtering apparatuses according to the previous embodiments, the above-described first additional shield 212 or the second additional shield 222 may not be located on the second side surface 112, which is a side surface of the first magnet assembly 110 toward the second magnet assembly 120, or the third side surface 123, which is a side surface of the second magnet assembly 120 toward the first magnet assembly 110. As such, the sputtering apparatus may have a simpler configuration.

Even in the sputtering apparatus according to the current embodiment, because the first shield 210 is located on the first side surface 111, which is a side surface of the first magnet assembly 110 in a direction (e.g., −x direction) opposite to another direction (e.g., +x direction) toward the second magnet assembly 120, and the second shield 220 is located on the fourth side surface 124, which is a side surface of the second magnet assembly 120 in a direction (e.g., +x direction) opposite to another direction (e.g., −x direction) toward the first magnet assembly 110, the parasitic plasma SP may not be generated or may be greatly reduced in its amount.

In the sputtering apparatus according to the current embodiment, as illustrated in FIG. 9, the first shield 210 may protrude from the first bottom surface 115 of the first magnet assembly 110 and the second shield 220 may protrude from the second bottom surface 125 of the second magnet assembly 120. Alternatively, the first shield 210′ may be bent to cover at least a portion of the first bottom surface 115 of the first magnet assembly 110 and the second shield 220′ may be bent to cover at least a portion of the second bottom surface 125 of the second magnet assembly 120.

Although the above-described sputtering apparatus is a dual rotating sputtering apparatus including the first and second magnet assemblies 110 and 120 and for mounting and rotating the first and second cylindrical tubular targets 410 and 420, the present invention is not limited thereto.

For example, a sputtering apparatus according to another embodiment of the present invention may include only one magnet assembly, and may dispose a shied on only one side surface of the magnet assembly or may dispose a shield on one side surface and dispose an additional shield on another side surface. In this case, the shield and/or the additional shield may protrude from a bottom surface of the magnet assembly, or may be bent to cover at least a portion(s) of the bottom surface of the magnet assembly.

A sputtering apparatus according to another embodiment of the present invention may be a dual rotating sputtering apparatus including two magnet assemblies but having a structure different from the above-described structures. In the sputtering apparatus according to the current embodiment, the first shield 210′ for covering the first side surface 111, which is a −x direction side surface of the first magnet assembly 110 in the first cylindrical tubular target 410, may be bent to cover at least a portion of the first bottom surface 115 of the first magnet assembly 110, and the second shield 220′ for covering the fourth side surface 124, which is a +x direction side surface of the second magnet assembly 120 in the second cylindrical tubular target 420 may be bent to cover at least a portion of the second bottom surface 125 of the second magnet assembly 120. Alternatively, the first additional shield 212 for covering the second side surface 112 that is a +x direction side surface of the first magnet assembly 110 in the first cylindrical tubular target 410 may not be bent and may protrude from the first bottom surface 115 of the first magnet assembly 110, and the second additional shield 222 for covering the third side surface 123, which is a −x direction side surface of the second magnet assembly 120 in the second cylindrical tubular target 420, may not be bent and may protrude from the second bottom surface 125 of the second magnet assembly 120.

In another embodiment, the first shield 210 for covering the first side surface 111, which is a −x direction side surface of the first magnet assembly 110 in the first cylindrical tubular target 410, may not be bent and may protrude from the first bottom surface 115 of the first magnet assembly 110, the second shield 220 for covering the fourth side surface 124, which is a +x direction side surface of the second magnet assembly 120 in the second cylindrical tubular target 420, may not be bent and may protrude from the second bottom surface 125 of the second magnet assembly 120, the first additional shield 212′ for covering the second side surface 112, which is a +x direction side surface of the first magnet assembly 110 in the first cylindrical tubular target 410, may be bent to cover at least a portion of the first bottom surface 115 of the first magnet assembly 110, and the second additional shield 222′ for covering the third side surface 123, which is a −x direction side surface of the second magnet assembly 120 in the second cylindrical tubular target 420, may be bent to cover at least a portion of the second bottom surface 125 of the second magnet assembly 120.

According to the above-described embodiments of the present invention, a sputtering apparatus capable of effectively reducing damage of a target in a sputtering process may be achieved. However, the present invention is not limited to the above described embodiments.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A sputtering apparatus comprising:
a first magnet assembly extending in a first direction, comprising a first side surface and a second side surface each extending in the first direction, which correspond to each other, and comprising a first bottom surface extending in the first direction, which connects the first side surface and the second side surface;
a first shield on the first side surface of the first magnet assembly; and
a first supporter for supporting a first end and a second end of a first cylindrical tubular target, the first cylindrical tubular target having a first longitudinal axis parallel to the first direction,
wherein the first cylindrical tubular target accommodates the first magnet assembly and the first shield.

2. The sputtering apparatus of claim 1, wherein the first supporter comprises a first motor configured to rotate the first cylindrical tubular target about the first longitudinal axis.

3. The sputtering apparatus of claim 1, wherein the first shield extends in the first direction along the first side surface of the first magnet assembly.

4. The sputtering apparatus of claim 1, wherein the first shield protrudes from the first bottom surface of the first magnet assembly.

5. The sputtering apparatus of claim 1, wherein the first shield is on at least a portion of the first bottom surface of the first magnet assembly.

6. The sputtering apparatus of claim 1, comprising a first additional shield on the second side surface of the first magnet assembly.

7. The sputtering apparatus of claim 1, wherein the first shield is configured to reduce an intensity of a magnetic field in an outer region of the first shield with respect to the first magnet assembly.

8. The sputtering apparatus of claim 1, further comprising:
a second magnet assembly extending in the first direction, comprising a third side surface and a fourth side surface each extending in the first direction, which correspond to each other, and comprising a second bottom surface extending in the first direction, which connects the third and fourth side surfaces, wherein the third side surface is adjacent to the second side surface of the first magnet assembly;
a second shield on the fourth side surface of the second magnet assembly; and
a second supporter for supporting a first end and a second end of a second cylindrical tubular target, the second cylindrical tubular target having a second longitudinal axis parallel to the first direction,
wherein the second cylindrical tubular target accommodates the second magnet assembly and the second shield.

9. The sputtering apparatus of claim 8, wherein the second supporter comprises a second motor configured to rotate the second cylindrical tubular target about the second longitudinal axis.

10. The sputtering apparatus of claim 8, wherein the second shield protrudes from the second bottom surface of the second magnet assembly.

11. The sputtering apparatus of claim 8, wherein the second shield is on at least a portion of the second bottom surface of the second magnet assembly.

12. The sputtering apparatus of claim 8, further comprising a second additional shield on the third side surface of the second magnet assembly.

13. The sputtering apparatus of claim 8, wherein the second shield is configured to reduce an intensity of a magnetic field in an outer region of the second shield with respect to the second magnet assembly.

14. A sputtering apparatus comprising:
a first magnet assembly extending in a first direction, comprising a first side surface and a second side surface each extending in the first direction, which correspond to each other, and comprising a first bottom surface extending in the first direction, which connects the first side surface and the second side surface;
a first shield on the first side surface of the first magnet assembly and protruding from the first bottom surface of the first magnet assembly;
a first additional shield on the second side surface of the first magnet assembly and protruding from the first bottom surface of the first magnet assembly;
a second magnet assembly extending in the first direction, comprising a third side surface and a fourth side surface extending in the first direction, which correspond to each other, and comprising a second bottom surface extending in the first direction, which connects the third side surface and the fourth side surface, wherein the third side surface is adjacent to the second side surface of the first magnet assembly;
a second shield on the fourth side surface of the second magnet assembly and protruding from the second bottom surface of the second magnet assembly;
a second additional shield on the third side surface of the second magnet assembly and protruding from the second bottom surface of the second magnet assembly;
a first supporter for supporting a first end and a second end of a first cylindrical tubular target, the first cylindrical tubular target having a first longitudinal axis parallel to the first direction, wherein the first cylindrical tubular target accommodates the first magnet assembly and the first shield; and
a second supporter for supporting a first end and a second end of a second cylindrical tubular target, the second cylindrical tubular target having a second longitudinal axis parallel to the first direction, wherein the second cylindrical tubular target accommodates the second magnet assembly and the second shield.

15. The sputtering apparatus of claim 14, wherein the first shield is configured to reduce an intensity of a magnetic field in an outer region of the first shield with respect to the first magnet assembly, and
wherein the second shield is configured to reduce an intensity of a magnetic field in an outer region of the second shield with respect to the second magnet assembly.

16. A sputtering apparatus comprising:
a first magnet assembly extending in a first direction, comprising a first side surface and a second side surface each extending in the first direction, which correspond to each other, and comprising a first bottom surface extending in the first direction, which connects the first side surface and the second side surface;
a first shield on the first side surface of the first magnet assembly and on at least a portion of the first bottom surface of the first magnet assembly;
a first additional shield on the second side surface of the first magnet assembly and on at least a portion of the first bottom surface of the first magnet assembly;
a second magnet assembly extending in the first direction, comprising a third side surface and a fourth side surface extending in the first direction, which correspond to each other, and comprising a second bottom surface extending in the first direction, which connects the third side surface and the fourth side surface, wherein the third side surface is adjacent to the second side surface of the first magnet assembly;
a second shield on the fourth side surface of the second magnet assembly and on at least a portion of the second bottom surface of the second magnet assembly;
a second additional shield on the third side surface of the second magnet assembly and on at least a portion of the second bottom surface of the second magnet assembly;
a first supporter for supporting a first end and a second end of a first cylindrical tubular target, the first cylindrical tubular target having a first longitudinal axis parallel to the first direction, wherein the first cylindrical tubular target accommodates the first magnet assembly and the first shield; and
a second supporter for supporting a first end and a second end of a second cylindrical tubular target, the second cylindrical tubular target having a second longitudinal axis parallel to the first direction, wherein the second cylindrical tubular target accommodates the second magnet assembly and the second shield.

17. The sputtering apparatus of claim 16, wherein the first shield is configured to reduce an intensity of a magnetic field in an outer region of the first shield with respect to the first magnet assembly, and
wherein the second shield is configured to reduce an intensity of a magnetic field in an outer region of the second shield with respect to the second magnet assembly.
